(19) United States
(12) Patent Application Publication
(10) Pub. No.: US 2026/0059702 A1
(43) Pub. Date: Feb. 26, 2026

(54) COOLING ASSEMBLY FOR CONTACTLESS DRIVE STRUCTURE OF COMPUTER

(71) Applicant: Garsendee Technology Co., Ltd, Dongguan (CN)

(72) Inventors: Hongming ZHU, Yueqing (CN); Zhicheng LIN, Guangzhou (CN)

(73) Assignee: Garsendee Technology Co., Ltd, Dongguan (CN)

(21) Appl. No.: 19/327,253

(22) Filed: Sep. 12, 2025

Related U.S. Application Data
(63) Continuation-in-part of application No. 18/884,390, filed on Sep. 13, 2024.

(30) Foreign Application Priority Data
Aug. 21, 2024 (CN) 202422037070.6
Jul. 1, 2025 (CN) 202510907094.9

(51) Int. Cl. H05K 7/20; G06F 1/20

(52) U.S. Cl. CPC H05K 7/20272; G06F 1/20; G06F 2200/201

(57) ABSTRACT

A cooling assembly for a contactless drive structure of a computer includes a water chamber and a drive device. The water chamber is a housing provided with an inner cavity, a pivotally mounted impeller is arranged on a top wall of the inner cavity; a disc is arranged on an upper portion of the impeller and extends radially from the impeller; the housing is provided with a fluid inlet and a fluid outlet; the drive device includes a pump base arranged on an upper wall of the water chamber; the pump base is fixedly provided with a stator; the stator is provided with a rotor, and the stator and the rotor are arranged radially; the rotor is located below the stator, and magnetic fields of the stator and the rotor are axially tangent to each other; the rotor is arranged on the disc.

### CROSS-REFERENCE TO RELATED APPLICATIONS

The present application is a continuation-in-part of U.S. patent application Ser. No. 18/884,390, filed on Sep. 13, 2024, which claims priority to Chinese Patent Application No. 202422037070.6, filed on Aug. 21, 2024. The present application also claims priority to Chinese Patent Application No. 202510907094.9, filed on Jul. 1, 2025. All of the aforementioned applications are incorporated herein by reference in their entireties.

### TECHNICAL FIELD

The present disclosure relates to the field of cooling radiators, in particular to a cooling assembly for a contactless drive structure of a computer.

### BACKGROUND

Computer water cooling refers to a liquid cooling system commonly used in a computer, and a liquid with a high specific heat coefficient (such as water) is used as a medium to help dissipate heat from internal components. Computer water cooling generally has the following advantages: small temperature fluctuations under the action of cyclic cooling, obvious temperature control effect on cooled components, and stable and reliable performance during long-term use.

In the existing integrated design of water pumps and water chambers, in order to drive an impeller by a brushless motor, a rotor is generally arranged inside the impeller. However, a magnetic induction coil of a stator needs to be tangent to a device (that is, the stator is a magnetic induction coil, and the rotor is arranged on the outer circumference of the stator, forming a radial tangency). As a result, a housing protrudes and extends into a water chamber to enable the impeller to drive the fluid to flow. Corresponding problems are that the water chamber has a relatively large volume and a relatively large thickness; moreover, the housing of the stator extends into the water chamber, and the volume of the water chamber is reduced accordingly.

Certainly, there are also structures in which the water pump and the water chamber are separated. Correspondingly, these structures are poor in integrity. Moreover, with the arrangement of a transparent chassis, the water pump and the water chamber are relatively large, and the overall aesthetics of the chassis is also affected.

### SUMMARY

The main objective of the present disclosure is to provide a cooling assembly for a contactless drive structure of a computer, aiming to realize integrated arrangement of the water pump and the water chamber with a simple structure, and to reduce the overall volume while ensuring the volume of the water chamber.

To achieve the above objective, the present disclosure provides a cooling assembly for a contactless drive structure of a computer, including:
a water chamber, wherein the water chamber is a housing provided with an inner cavity; a pivotally mounted impeller is arranged on a top wall of the inner cavity; a disc is arranged on an upper portion of the impeller, and the disc extends radially from the impeller;
the housing is provided with a fluid inlet and a fluid outlet;
a drive device, wherein the drive device includes a pump base arranged on an upper wall of the water chamber; the pump base is fixedly provided with a stator; the stator is provided with a rotor, and the rotor cooperates with the stator; and the rotor and the stator are arranged radially, the rotor is located below the stator, and magnetic fields of the stator and the rotor are axially tangent to each other;
the rotor is arranged on the disc, or the rotor drives the disc to rotate through an intermediate member;
a top wall of the water chamber is a partition plate arranged between the stator and the disc; and
when the impeller rotates, the impeller is arranged to drive fluid to flow from the fluid inlet, through the water chamber, and into the fluid outlet.

In actual design, the water chamber is a relatively closed housing. Therefore, a pivotable impeller is arranged on the top wall of the water chamber, such that the impeller and the pump housing are not connected to each other. Through the axially arranged stator, the axially arranged rotor is driven to rotate. The rotor is directly arranged on the disc, or the rotor is arranged to drive the disc to rotate through an intermediate member.

The advantages are as follows.

The water chamber and the pump base are two independent chambers, so the fluid will not affect circuit elements, thereby ensuring the service life and safety of the drive device.

The stator and the rotor are arranged radially to achieve axial tangency, such that the overall thickness of the drive device is reduced. At the same time, an integrated structure of the water chamber and the pump base has a smaller volume, thereby effectively improving the aesthetics of a computer water cooling structure.

The structure is simpler. No concave-convex structure is required between the water chamber and the pump chamber to realize the tangency of the stator and the rotor; and a radial structure is sufficient. Therefore, the production cost of a mold is lower, and market competitiveness is effectively enhanced.

Under the same output torque, rotational speed and power, compared with a radial flux motor, an axial flux motor (i.e., the drive device in the present disclosure) has an axial dimension shortened by more than 50%, making it more suitable for occasions with high space requirements; the weight is reduced by about 50%, thereby further improving the mobility of the device and achieving lightweight design.

The direction of the pump base is vertical or horizontal.

The rotor and the impeller are not in rigid connection. When the impeller resistance exceeds a predetermined value, the motor (i.e., a magnetic induction coil) will not burn out due to an internal resistance.

In particular, for problems that the rotor may be jammed or moves slowly when greater power is output after internal blockage of some pumps (i.e., requiring greater torque output), the service life of the water pump is effectively prolonged.

### BRIEF DESCRIPTION OF THE DRAWINGS

For convenience of description, the “cooling assembly for a contactless drive structure of a computer” is abbreviated as the “cooling assembly”. In the drawings:

FIG. 1 is an exploded view I of the cooling assembly in the first embodiment;

FIG. 2 is an exploded view II of the cooling assembly in the first embodiment;

FIG. 3 is a half-sectional schematic view of the cooling assembly in the first embodiment;

FIG. 4 is a cross-sectional view of the cooling assembly in the first embodiment;

FIG. 5 is a schematic view of the water chamber;

FIG. 6 is a half-sectional schematic view of the position of a flow guide seat;

FIG. 7 is a top view of the flow guide seat;

FIG. 8 is a schematic view of the cooperation between the rotor and the stator;

FIG. 9 is an exploded view I of the cooling assembly in the third embodiment;

FIG. 10 is an exploded view II of the cooling assembly in the third embodiment;

FIG. 11 is a cross-sectional view of the cooling assembly at the rotating shaft portion in the third embodiment;

FIG. 12 is a cross-sectional view of the cooling assembly at the position of the fluid outlet in the third embodiment;

FIG. 13 is a cross-sectional view of the cooling assembly at the position of the fluid inlet in the third embodiment; and

FIG. 14 is a schematic view of the cooling assembly in the third embodiment with the upper shell being hidden.

### DETAILED DESCRIPTION OF THE EMBODIMENTS

The technical solutions in the embodiments of the present disclosure will be clearly and completely described below with reference to the accompanying drawings. Apparently, the described embodiments are merely a part rather than all of the embodiments of the present disclosure. Based on the embodiments of the present disclosure, all the other embodiments obtained by those skilled in the art without any creative effort shall fall within the protection scope of the present disclosure.

It should be noted that if there are directional indications involved in the embodiments of the present disclosure (such as upper, lower, left, right, front, rear, top, bottom, inner, outer, vertical, horizontal, longitudinal, counterclockwise, clockwise, circumferential, radial, axial . . . ), these directional indications are merely used to explain the relative positional relationship, movement status and the like between components under a specific posture (as shown in the accompanying drawings). If the specific posture changes, the directional indications will also change accordingly.

In addition, if there are descriptions involving “first” or “second” in the embodiments of the present disclosure, such descriptions of “first” or “second” are merely for descriptive purposes, and may not be understood as indicating or implying their relative importance or implicitly specifying the number of indicated technical features. Therefore, the features defined with “first” and “second” may explicitly or implicitly include at least one such feature. In addition, the technical solutions between various embodiments are combined with each other, but must be based on the realization by those skilled in the art. When the combination of technical solutions is contradictory or may not be realized, it should be considered that such a combination of technical solutions does not exist and does not fall within the protection scope required by the present disclosure.

In the present disclosure, pivotal mounting refers to an installation method that realizes rotatable connection between components through a pivot or similar structure, and the core of pivotal mounting lies in allowing the connected components to rotate relatively around a fixed axis.

In the present disclosure, “the magnetic fields of the stator and the rotor are axially tangent to each other” means that the magnetic field of the stator and the magnetic field of the rotor form an axial tangential interaction relationship in spatial distribution, that is, the directions of the two magnetic fields are perpendicular to each other in the axial direction or are intersected at a specific angle, thereby generating a tangential electromagnetic force to drive the rotor to rotate.

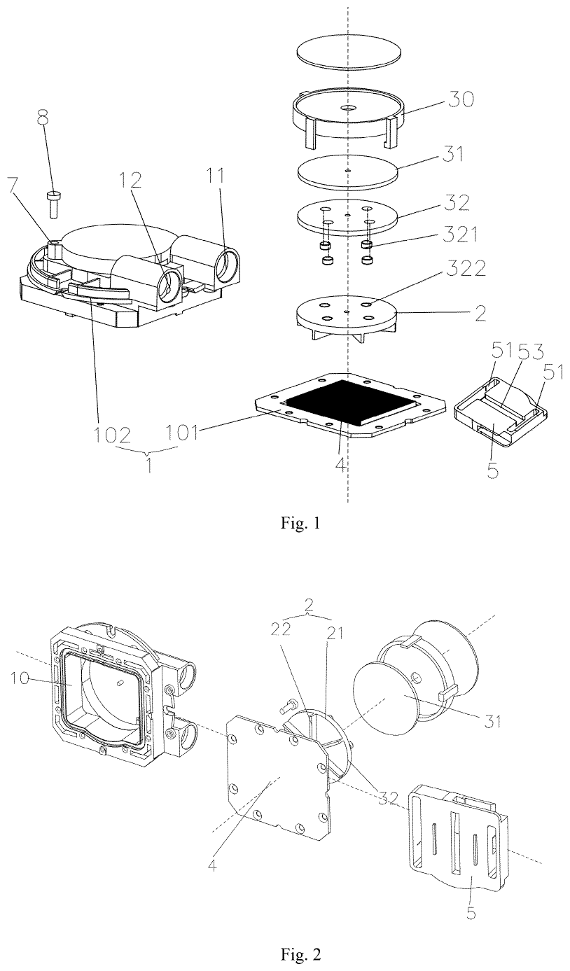

As shown in FIGS. 1 and 2, in the first embodiment, a cooling assembly for a contactless drive structure of a computer includes:

A water chamber 1, wherein the water chamber 1 is a housing provided with an inner cavity 10 (the housing includes an upper shell 102 and a bottom cover 101; the flow distribution layer 40 and the bottom cover 101 are integrally formed; a lower end of the upper shell 102 is provided with an opening, and the opening is provided with a clamping groove for installing a sealing ring to relatively seal the opening and the bottom cover 101); a pivotally mounted impeller 2 is arranged on a top wall of the inner cavity 10, a disc 21 is arranged on an upper portion of the impeller 2, and the disc 21 extends radially from the impeller 2.

The housing is provided with a fluid inlet 11 and a fluid outlet 12.

A drive device 3, wherein the drive device 3 includes a pump base 30 arranged on an upper wall of the water chamber 1; the pump base 30 is fixedly provided with a stator 31; the stator 31 is provided with a rotor 32, and the rotor 32 cooperates with the stator 31; and the rotor 32 and the stator 31 are arranged radially, the rotor 32 is located below the stator 31, and magnetic fields of the stator 31 and the rotor 32 are axially tangent to each other.

The rotor 32 is arranged on the disc 21, or the rotor 32 drives the disc 21 to rotate through intermediate members (i.e., the first magnetic member 321 and the second magnetic member 322).

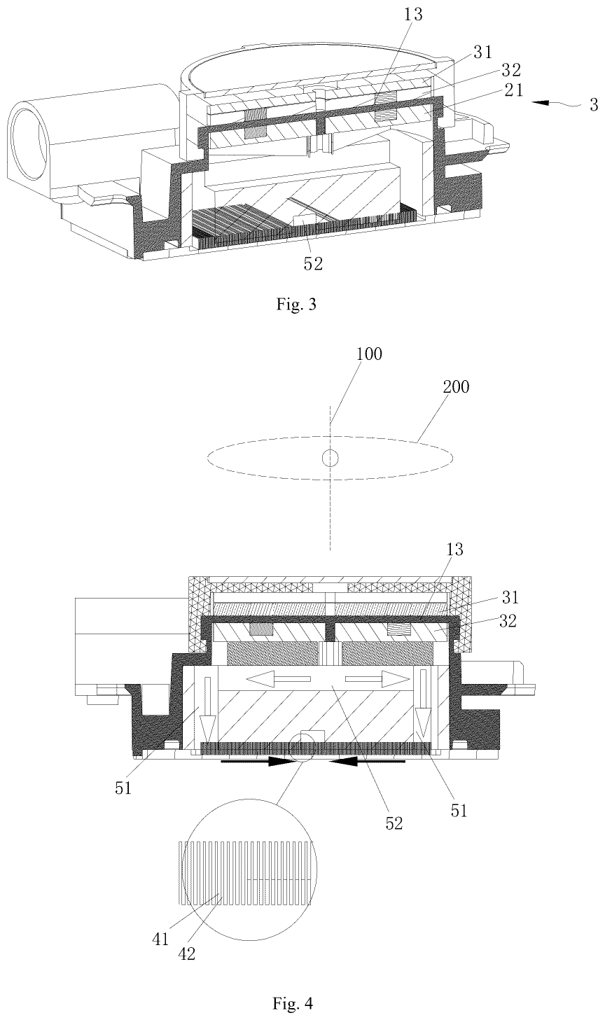

As shown in FIGS. 1 and 3, a top wall of the water chamber 1 is a partition plate 13 arranged between the stator 31 and the disc 21.

When the impeller 2 rotates, the impeller 2 is arranged to drive fluid to flow from the fluid inlet 11, through the water chamber 1, and into the fluid outlet 12.

In actual design, the water chamber 1 is a relatively closed housing. Therefore, a pivotable impeller 2 is arranged on the top wall of the water chamber 1, such that the impeller 2 and the pump housing are not connected to each other. Through the axially arranged stator 31, the axially arranged rotor 32 is driven to rotate. The rotor 32 is directly arranged on the disc 21, or the rotor 32 is arranged to drive the disc 21 to rotate through an intermediate member.

The advantages are as follows.

The water chamber 1 and the pump base 30 are two independent chambers, so the fluid will not affect circuit elements, thereby ensuring the service life and safety of the drive device 3.

The stator 31 and the rotor 32 are arranged radially to achieve axial tangency, such that the overall thickness of the drive device 3 is reduced. At the same time, an integrated structure of the water chamber 1 and the pump base 30 has a smaller volume, thereby effectively improving the aesthetics of a computer water cooling structure.

The structure is simpler. No concave-convex structure is required between the water chamber 1 and the pump chamber to realize the tangency of the stator 31 and the rotor 32; and a radial structure is sufficient. Therefore, the production cost of a mold is lower, and market competitiveness is effectively enhanced.

Under the same output torque, rotational speed and power, compared with a radial flux motor, an axial flux motor (i.e., the drive device 3 in the present disclosure) has an axial dimension shortened by more than 50%, making it more suitable for occasions with high space requirements; the weight is reduced by about 50%, thereby further improving the mobility of the device and achieving lightweight design.

The direction of the pump base 30 is vertical or horizontal.

Based on one or more of the above embodiments, as a preferred embodiment, a bottom wall of the water chamber 1 is a heat-conducting surface 4.

Based on one or more of the above embodiments, as a preferred embodiment, as shown in FIG. 2, a bottom wall of the inner cavity 10 includes a wall surface, the wall surface is arranged opposite to the heat-conducting surface 4, and the wall surface is provided with a protruding flow distribution layer 40. In actual design, a cold plate, the water chamber 1 and the pump base 30 are integrally arranged, such that the cooling assembly is directly installed on a heating element (such as a graphics card, a Central Processing Unit (CPU)). The volume is small and the stability is favorable; at the same time, the axial drive device 3 is adopted to reduce the overall thickness and weight, thereby facilitating the installation. The flow distribution layer 40 is configured to increase the contact area between the fluid and the bottom wall of the inner cavity 10, and further improve the heat exchange effect of a flow guide surface.

Based on one or more of the above embodiments, as a preferred embodiment, as shown in FIG. 4, the flow distribution layer 40 includes a plurality of heat-conducting strips 41 arranged at intervals, and a flow guide groove 42 is enclosed between two adjacent heat-conducting strips 41, such that the fluid flows in a predetermined direction and the heat exchange efficiency is improved.

Based on one or more of the above embodiments, as a preferred embodiment, the stator 31 includes a bracket 310 and the magnetic induction coils 311, and the magnetic induction coils 311 are arranged on the bracket 310 at intervals.

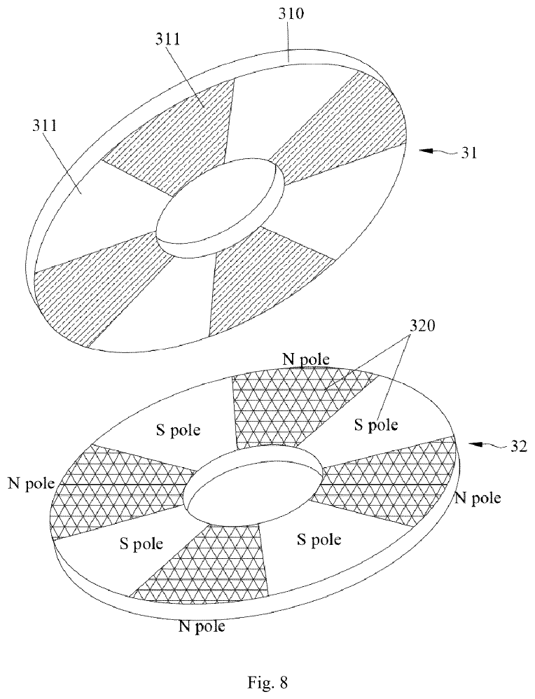

As shown in FIGS. 4 and 8, a magnetic induction direction of each one of the magnetic induction coils 311 is an axial direction 100. The rotor 32 is provided with a plurality of permanent magnets 320. The structure is referred to as an axial flux motor, and the rotation of the rotor 32 is controlled by controlling the direction of the current. Referring to FIG. 4, the radial direction 200 is perpendicular to the axial direction 100.

Based on one or more of the above embodiments, as a preferred embodiment, when the permanent magnets 320 are arranged on the disc 21, the stator 31 directly drives the permanent magnets 320, thereby driving the impeller 2 to rotate. As shown in FIG. 4, a partition plate 13 is arranged between the stator 31 and the rotor 32. This structure eliminates an air gap, thereby solving the problem of unstable heat dissipation of the axial flux motor, that is, the rotor 32 is located in the water chamber 1 and is configured to fully dissipate heat. In principle, the magnetic fields of the permanent magnets 320 are stable, then correspondingly the main damaged component is the stator 31 (i.e., the magnetic induction coil 311). Therefore, even if the cooling assembly is damaged, the stator 31 is replaced to effectively improve the convenience of maintenance.

Based on one or more of the above embodiments, as a preferred embodiment, the rotor 32 and the disc 21 are integrally injection-molded, thereby effectively protecting the structure of the stator 31 and improving the stability of the permanent magnets 320.

Based on one or more of the above embodiments, as a preferred embodiment, the projected areas of the magnetic fields of the stator 31 and the rotor 32 in the axial direction 100 are substantially the same, thereby ensuring the driving stability and avoiding the problem of magnetic field loss. “Substantially the same” includes being completely the same, or an absolute value of the difference between the two being within a preset range.

Based on one or more of the above embodiments, as a preferred embodiment, each one of the permanent magnets 320 is fan-shaped and is annularly distributed on the rotor 32.

Each one of the permanent magnets 320 includes a South (S) pole and a North (N) pole, and the S pole and the N pole are arranged adjacent to each other to realize a tangential magnetic field.

Referring to FIGS. 1 and 4, in the second embodiment, the rotor 32 is pivotally mounted between the upper wall of the water chamber 1 and the pump base 30. The rotor is provided with a first magnetic member, and the first magnetic member is one of the permanent magnets. The disc 21 is provided with a second magnetic member 322 that cooperates with the first magnetic member 321, and the partition plate 13 is arranged between the rotor 32 and the disc 21. Generally speaking, the rotor 32 is also provided with structures such as an iron core for fixing the permanent magnets 320. When the permanent magnets 320 are integrally injection-molded, the use of the iron core is also reduced to fix magnetic poles of the permanent magnets 320.

Specifically, the bracket 310 is a PCB or an iron core. In actual design, a PCB is preferably used to wind magnetic induction coils 311, such that the circuit is conveniently controlled and has a smaller thickness.

Specifically, the drive device 3 is installed on the pump base 30, and the pump base 30 is detachably installed on the upper wall of the housing, thereby facilitating maintenance or replacement.

Specifically, the outer peripheral wall or upper wall of the housing is provided with clamping holes, and both sides of the pump base 30 are provided with clamping hooks that cooperate with the clamping holes. The clamping hooks extend into the clamping holes for hooking. Of course, the pump housing is also fixed by screws to facilitate installation.

Based on one or more of the above embodiments, as a preferred embodiment, the impeller 2 includes blades 22 arranged on a lower wall of the disc 21, and the blades 22 are distributed at intervals along an outer circumference of the disc 21 about an axis of the disc 21. Specifically, the blades are arc-shaped, strip-shaped or curved-surface structures to enable the fluid to flow in a predetermined direction.

Specifically, the water chamber 1 is provided with a flow guide seat 5, and the flow guide seat 5 is provided with a flow distribution channel. The impeller 2 is arranged to drive fluid to sequentially pass through the fluid inlet 11, the flow distribution channel and the flow distribution layer 40, and flow to the fluid outlet 12. The flow guide seat 5 is arranged to reduce the generation of turbulent flow, enable the fluid to flow in an orderly manner, and further improve the heat dissipation effect.

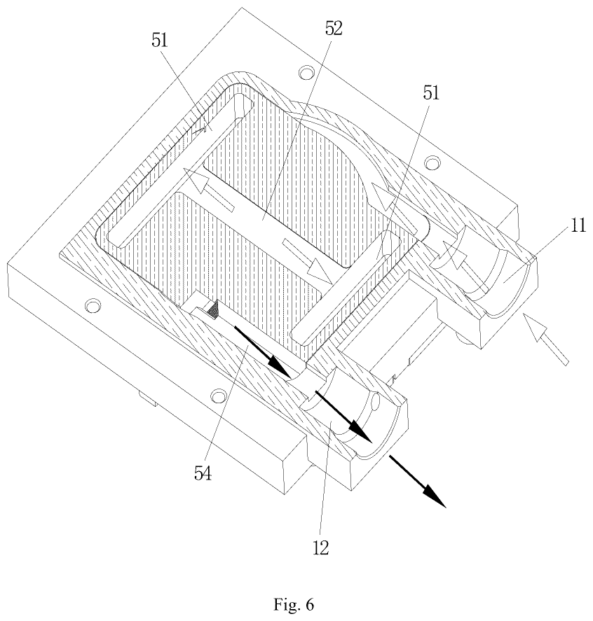

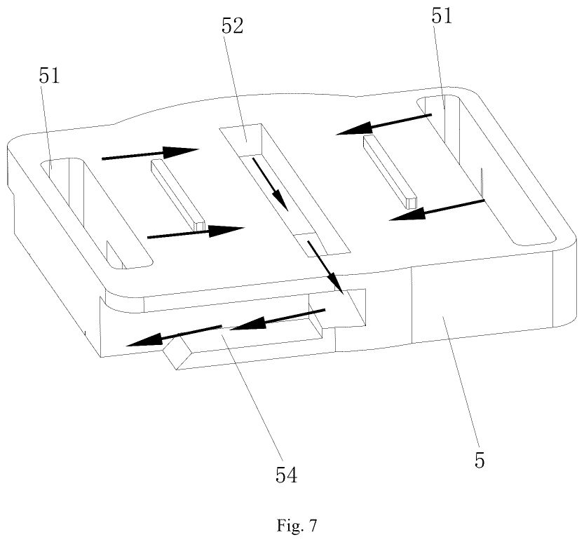

Specifically, as shown in FIGS. 3, 4, 6 and 7, the flow distribution channel includes two first flow channels 51 arranged at intervals and a second flow channel 52 arranged on the bottom wall of the flow guide seat 5. The first flow channel 51 is arranged through the flow guide seat 5, the lower end of the first flow channel 51 is connected to the flow distribution layer 40, and the fluid flows to the second flow channel 52 after passing through the flow distribution layer 40.

The upper wall of the flow guide seat 5 is provided with a groove 53 that connects the two first flow channels 51. When the impeller 2 rotates, the fluid generally flows outwards from the axis to generate fluid pressure. Therefore, by arranging flow distribution channels on both sides, the fluid flows from both ends of the flow distribution layer 40 towards the middle, and finally flows to the fluid outlet 12 through the second flow channel 52 in the middle.

Specifically, the end of the flow guide seat 5 is provided with a through groove 54, the through groove 54 is connected to the fluid outlet 12, and the second flow channel 52 is bent and extends through the through groove 54.

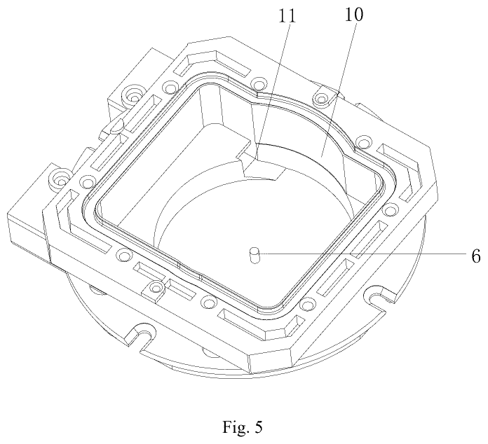

Specifically, as shown in FIG. 5, a first rotating shaft 6 extends downwards from the top wall of the inner cavity 10, and the first rotating shaft is configured to install the impeller 2.

Specifically, a bearing is arranged between the rotating shaft and the impeller 2, and the bearing is a corrosion-resistant structure such as a ceramic bearing, so as to improve the stability during use.

Specifically, the pump base 30 is provided with a pivot portion, and the pivot portion is configured to install the rotor 32 to realize rotation. Of course, for a disc-shaped rotor 32, the pivot portion may also be a bearing arranged on the outer side of the rotor 32, or a second rotating shaft arranged in the middle of the rotor 32, or bearings arranged on both the inner and outer sides of the device.

As shown in FIG. 1, the water chamber is provided with a through hole 7 extending into the inner cavity, and a sensor 8 is detachably installed in the through hole; the sensor 8 is configured to detect the water temperature, water quality, fluid pressure and liquid level of the fluid in the inner cavity; the sensor is connected to a control device, the control device is also connected with the drive device, and the control device is configured to control the rotational speed of the impeller according to the data of the sensor. The sensor is connected to the drive device through wires, because the drive device integrates a control board (that is, the control device is arranged in the drive device). At the same time, the control device also integrates a wireless transceiver, then the drive device is directly controlled without a computer interface. Only the water pump needs to be powered, thereby reducing the number of exposed wires. At the same time, the data of the sensor will be involved in calculating the rotational speed strategy of the water pump.

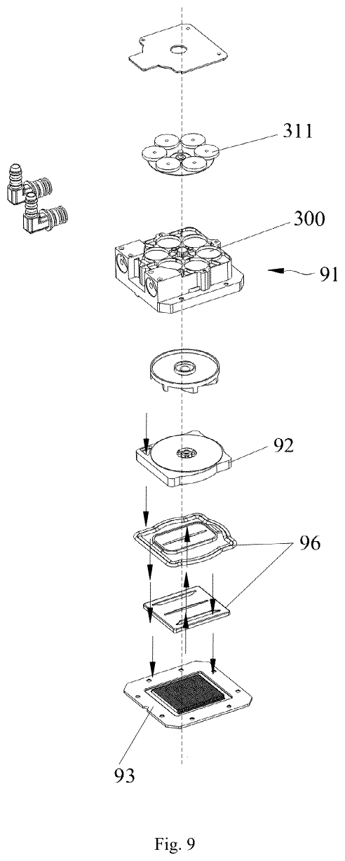

As shown in FIG. 9, in the third embodiment, a top wall of the housing (i.e., the water chamber 1) is provided with a plurality of positioning grooves 300.

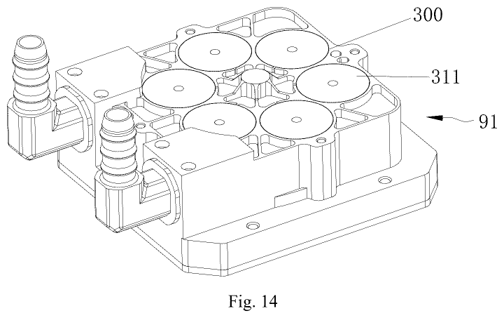

As shown in FIG. 14, the positioning grooves 300 are configured to mount magnetic induction coils 311.

The magnetic induction coils 311 are configured to apply axial magnetic tangents to drive the impeller to rotate.

Different from the existing design, the magnetic induction coil is directly installed in the positioning groove 300 as an independent individual, and further a higher inductance of the magnetic induction coil is realized, and a greater driving force is generated, thereby providing a higher rotational speed when the permanent magnet and the magnetic induction coil are tangent, and improving the stability of the device.

Specifically, the positioning grooves 300 are distributed at intervals along the circumference of the same axis.

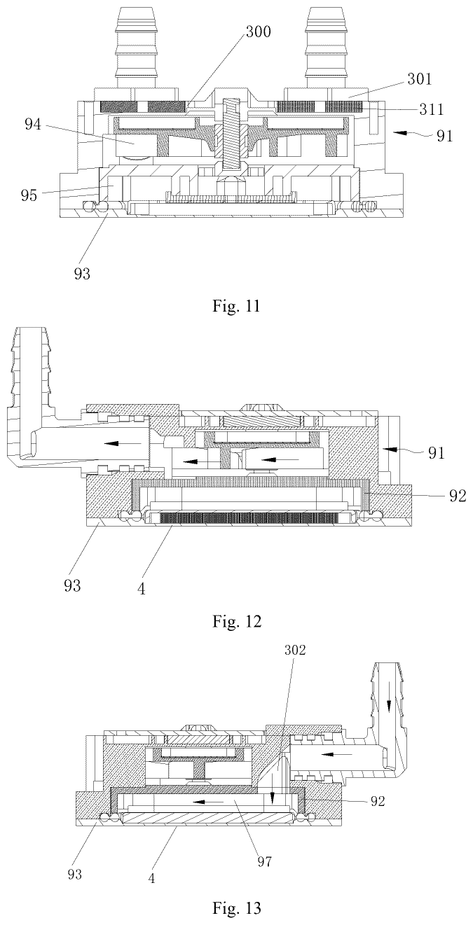

Based on one or more of the above embodiments, as a preferred embodiment, referring to FIG. 11, the magnetic induction coils 311 are connected to the control device via a PCB 301, or the magnetic induction coils 311 are connected to the control device via cables. Different connection methods facilitate the electrical connection of the magnetic induction coil.

For example, when cables are used, independent interfaces are adopted to connect with the control device respectively.

When a PCB 301 is adopted, the magnetic induction coil is also welded to the PCB 301 and then installed in the positioning groove 300, thereby realizing the installation and fixation of the magnetic induction coil 311.

For example, the PCB 301 is directly installed by screw rods.

When the PCB 301 is not used for fixation, the magnetic induction coil 311 is also fixed by a positioning cover plate.

Based on one or more of the above embodiments, as a preferred embodiment, the magnetic induction coils 311 are independent modules, and each one of the magnetic induction coils 311 is composed of a copper wire having a predetermined thickness wound into a coil.

Based on one or more of the above embodiments, as a preferred embodiment, the magnetic induction coils 311 are magnetic levitation coils, and a small magnetic levitation coil is adopted to generate axial inductance when energized.

When a plurality of circumferentially distributed magnetic induction coils are energized in a predetermined sequence, the permanent magnet is driven.

Based on one or more of the above embodiments, as a preferred embodiment, the control device is configured to control a plurality of magnetic induction coils 311 to be energized in a predetermined sequence and/or direction, thereby realizing the rotation of the impeller 2, wherein the direction of rotation is related to the energization frequency and inductance.

The magnetic induction coils are connected to the control device in a series or parallel manner.

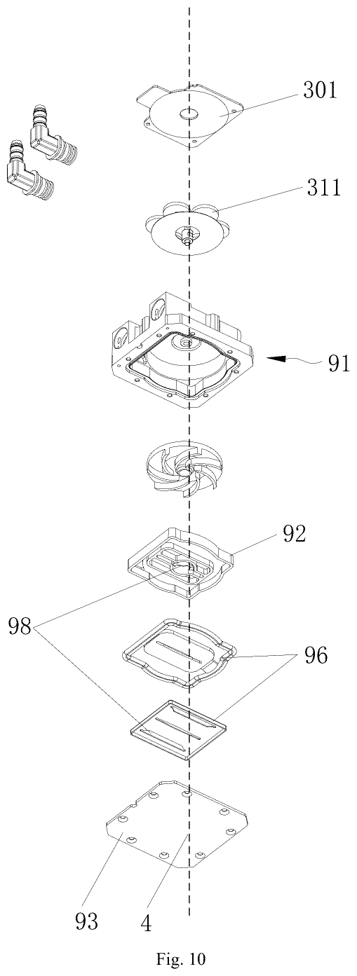

Based on one or more of the above embodiments, as a preferred embodiment, as shown in FIGS. 10, 11 and 12, the housing includes a top shell 91, a middle shell 92 and a heat dissipation plate 93.

A lower end of the top shell 91 is provided with an opening, and the top shell 91 is provided with the inner cavity 10.

The middle shell 92 is arranged in a middle portion of the inner cavity 10, and the middle shell 92 divides the inner cavity 10 into an upper chamber 94 and a lower chamber 95.

The impeller is pivotally mounted in the upper chamber 94, and is located between a top wall of the top shell 91 and a top wall of the middle shell 92.

The heat dissipation plate 93 is arranged in the opening.

The lower chamber 95 is enclosed between an upper wall of the heat dissipation plate 93 and a lower wall of the middle shell 92.

The lower chamber 95 is provided with a flow distribution plate 96, and the flow distribution plate 96 divides the lower chamber 95 into a water inlet channel 97 and a water outlet channel 98.

The heat dissipation plate 93 is provided with a heat exchange channel.

Specifically, the flow distribution plate 96 is a single piece or a combination of two pieces. The water inlet channel 97 is arranged on the outer circumference; after passing through a heat sink structure of the heat dissipation plate 93, the fluid flows into the middle shell 92 through the water outlet channel in the middle, then the fluid enters the upper chamber 94 through the channel of the middle shell 92, and is delivered to the fluid outlet by the impeller 2.

Referring to FIGS. 11, 12 and 13, the fluid sequentially passes through the fluid inlet 11, the water inlet channel 97, the heat exchange channel of the heat dissipation plate 93, the water outlet channel 98, the upper chamber 94 and the fluid outlet 12.

Based on one or more of the above embodiments, as a preferred embodiment, the water inlet channel 97 is in an annular structure or are distributed in an annular shape (e.g., the water inlet channel 97 is composed of two, three or four circumferentially distributed grooves). The annular structure may be a closed-loop circular ring (i.e., a closed-loop channel) or an intermittently arranged ring structure.

The traditional design in which fluid flows from the middle to the outer circumference is changed, and the flow channel is changed.

The travel length of the fluid is increased, the uniformity of fluid flow rate is improved, and bubbles are reduced.

The fluid enters the heat exchange channel of the heat dissipation plate 93 through the annular structure, and then enters the upper chamber 94 through the water outlet channel in the middle of the flow distribution plate 96.

Based on one or more of the above embodiments, as a preferred embodiment, the water outlet channel 98 is arranged in the middle position of the flow distribution plate 96.

Based on one or more of the above embodiments, as a preferred embodiment, the middle shell 92 is provided with a through channel, one end of the through channel is connected to the water outlet channel, and another end of the through channel extends into the upper chamber 94.

Based on one or more of the above embodiments, as a preferred embodiment, the middle portion of the inner cavity 10 is provided with an inwardly protruding stepped portion. The stepped portion is configured to be attached to the middle shell 92 and support the middle shell 92. Different from the existing assembly structure of the housing, in the present application, a single top shell 91 is adopted, then the middle shell 92 and the flow distribution plate 96 are installed, and finally the heat dissipation plate 93 is installed to form a relatively closed water chamber.

The problem of the existing structure in which a plurality of housings enclose a plurality of chambers is solved, thereby effectively improving the structural stability and sealing performance, and reducing the risk of liquid leakage.

Moreover, the design of a stepped portion effectively improves the compactness of the structure, making the overall thickness of the structure smaller.

Specifically, the inner end of the fluid outlet is arranged at the position of the upper chamber.

Based on one or more of the above embodiments, as a preferred embodiment, as shown in FIG. 13, the fluid inlet is integrally formed with the top shell and forms a bent pipe 302 via the stepped portion, and an inner end of the bent pipe 302 extends into the lower chamber 95.

An inner end of the fluid outlet 12 is arranged in the upper chamber 94.

The above descriptions are merely preferred embodiments of the present disclosure, and are not intended to limit the patent scope of the present disclosure. All equivalent structural transformations made by using the contents of the specification and drawings of the present disclosure under the inventive concept of the present disclosure, or direct/indirect applications in other related technical fields, are included in the patent protection scope of the present disclosure.

What is claimed is:

1. A cooling assembly for a contactless drive structure of a computer, comprising:
a water chamber, wherein the water chamber is a housing provided with an inner cavity; a pivotally mounted impeller is arranged on a top wall of the inner cavity; a disc is arranged on an upper portion of the impeller, and the disc extends radially from the impeller; the housing is provided with a fluid inlet and a fluid outlet; and
a drive device, wherein the drive device comprises a pump base arranged on an upper wall of the water chamber; the pump base is fixedly provided with a stator; the stator is provided with a rotor, and the rotor cooperates with the stator; and the rotor and the stator are arranged radially, the rotor is located below the stator, and magnetic fields of the stator and the rotor are axially tangent to each other; wherein,
the rotor is arranged on the disc, or the rotor drives the disc to rotate through an intermediate member;
a top wall of the water chamber is a partition plate arranged between the stator and the disc;
when the impeller rotates, the impeller is arranged to drive fluid to flow from the fluid inlet, through the water chamber, and into the fluid outlet;
a top wall of the housing is provided with a plurality of positioning grooves;
the positioning grooves are configured to mount magnetic induction coils;
the magnetic induction coils are configured to apply axial magnetic tangents to drive the impeller to rotate; and
the positioning grooves are circumferentially distributed at intervals along a same axis.

2. The cooling assembly for the contactless drive structure of the computer according to claim 1, wherein a bottom wall of the water chamber comprises a heat-conducting surface.

3. The cooling assembly for the contactless drive structure of the computer according to claim 2, wherein a bottom wall of the inner cavity comprises a wall surface, the wall surface is opposite to the heat-conducting surface, and the wall surface is provided with a protruding flow distribution layer.

4. The cooling assembly for the contactless drive structure of the computer according to claim 3, wherein the flow distribution layer comprises a plurality of heat-conducting strips arranged at intervals, and a flow guide groove is enclosed between two adjacent heat-conducting strips.

5. The cooling assembly for the contactless drive structure of the computer according to claim 1, wherein the stator comprises a bracket and the magnetic induction coils, the magnetic induction coils are arranged on the bracket at intervals, and a magnetic induction direction of each one of the magnetic induction coils is an axial direction; and
the rotor is provided with a plurality of permanent magnets.

6. The cooling assembly for the contactless drive structure of the computer according to claim 5, wherein when the permanent magnets are arranged on the disc, the stator directly drives the permanent magnets, thereby driving the impeller to rotate, and the partition plate is arranged between the stator and the rotor.

7. The cooling assembly for the contactless drive structure of the computer according to claim 6, wherein the rotor and the disc are integrally injection-molded.

8. The cooling assembly for the contactless drive structure of the computer according to claim 5, wherein projected areas of the magnetic fields of the stator and the rotor in the axial direction are substantially the same.

9. The cooling assembly for the contactless drive structure of the computer according to claim 5, wherein each one of the permanent magnets is fan-shaped and is annularly distributed on the rotor; and each one of the permanent magnets includes a South (S) pole and a North (N) pole, and the S pole and N pole are arranged adjacent to each other.

10. The cooling assembly for the contactless drive structure of the computer according to claim 5, wherein the rotor is pivotally mounted between the upper wall of the water chamber and the pump base; and
the rotor is provided with a first magnetic member, the first magnetic member is one of the permanent magnets, and the partition plate is arranged between the rotor and the disc.

11. The cooling assembly for the contactless drive structure of the computer according to claim 1, wherein the impeller comprises blades arranged on a lower wall of the disc, and the blades are distributed at intervals along an outer circumference of the disc about an axis of the disc.

12. The cooling assembly for the contactless drive structure of the computer according to claim 1, wherein the magnetic induction coils are connected to a control device via a Printed Circuit Board (PCB), or the magnetic induction coils are connected to the control device via cables.

13. The cooling assembly for the contactless drive structure of the computer according to claim 1, wherein the magnetic induction coils are independent modules, and each one of the magnetic induction coils is composed of a copper wire having a predetermined thickness wound into a coil.

14. The cooling assembly for the contactless drive structure of the computer according to claim 1, wherein the magnetic induction coils are magnetic levitation coils.

15. The cooling assembly for the contactless drive structure of the computer according to claim 12, wherein the control device is configured to control a plurality of the magnetic induction coils to be energized in a predetermined sequence and/or direction.

16. The cooling assembly for the contactless drive structure of the computer according to claim 1, wherein the housing comprises a top shell, a middle shell and a heat dissipation plate;
a lower end of the top shell is provided with an opening, and the top shell is provided with the inner cavity;
the middle shell is arranged in a middle portion of the inner cavity, and the middle shell divides the inner cavity into an upper chamber and a lower chamber;
the impeller is pivotally mounted in the upper chamber, and the impeller is located between a top wall of the top shell and a top wall of the middle shell;
the heat dissipation plate is arranged in the opening;
the lower chamber is enclosed between an upper wall of the heat dissipation plate and a lower wall of the middle shell;
the lower chamber is provided with a flow distribution plate, and the flow distribution plate divides the lower chamber into a water inlet channel and a water outlet channel;
the heat dissipation plate is provided with a heat exchange channel; and
the fluid sequentially passes through the fluid inlet, the water inlet channel, the heat exchange channel, the water outlet channel, the upper chamber and the fluid outlet.

17. The cooling assembly for the contactless drive structure of the computer according to

16. wherein the middle portion of the inner cavity is provided with an inwardly protruding stepped portion; and the stepped portion is configured to be attached to the middle shell and support the middle shell;
the water inlet channel is annularly distributed or is a closed-loop channel;
the water outlet channel is formed on a middle portion of the flow distribution plate; and
the middle shell is provided with a through channel, one end of the through channel is connected to the water outlet channel, and another end of the through channel extends into the upper chamber.

18. The cooling assembly for the contactless drive structure of the computer according to claim 17, wherein the fluid inlet is integrally formed with the top shell and forms a bent pipe via the stepped portion, and an inner end of the bent pipe extends into the lower chamber; and
an inner end of the fluid outlet is arranged in the upper chamber.
